(19) United States
(12) Patent Application Publication
(10) Pub. No.: US 2026/0215261 A1
(43) Pub. Date: Jul. 23, 2026

(54) SEMICONDUCTOR PACKAGE AND METHOD OF MANUFACTURING THE SAME

(71) Applicant: JMJ Korea Co., Ltd., Busan (KR)

(72) Inventors: Yun Hwa CHOI, Busan (KR); Sangdu Park, Incheon (KR); HoSoub PARK, Busan (KR); JunHo Lee, Busan (KR)

(73) Assignee: JMJ Korea Co., Ltd., Busan (KR)

(21) Appl. No.: 19/095,060

(22) Filed: Mar. 31, 2025

(30) Foreign Application Priority Data
Jan. 23, 2025 (KR) 10-2025-0010133

(51) Int. Cl. H01L 23/367; H01L 21/48; H01L 21/56; H01L 23/29; H01L 23/31; H01L 23/373; H01L 23/473

(52) U.S. Cl. CPC H10W 40/228; H10W 40/22; H10W 40/255; H10W 40/47; H10W 70/02; H10W 74/014; H10W 74/016; H10W 74/111; H10W 74/47

(57) ABSTRACT

The present invention relates to a semiconductor package and a method of manufacturing the same, particularly, to a semiconductor package and a method of manufacturing the same by which joint strength of a heat sink may be improved while the package to which the heat sink is bonded is cooled, and more particularly, to a semiconductor package and a method of manufacturing the same by which thermal conductivity may be increased by using relatively thin metal pattern layers and heat release metal layers and heat emission effect occurring due to contact with a coolant may be increased by using a relatively thick heat sink.

### CROSS-REFERENCE TO RELATED PATENT APPLICATION

This application claims the benefit of Korean Patent Application No. 10-2025-0010133, filed on Jan. 23, 2025, in the Korean Intellectual Property Office, the disclosure of which is incorporated herein in its entirety by reference.

### BACKGROUND OF THE INVENTION

### 1. Field of the Invention

The present invention relates to a semiconductor package and a method of manufacturing the same, particularly, to a semiconductor package and a method of manufacturing the same by which joint strength of a heat sink may be improved while the package to which the heat sink is bonded is cooled, and more particularly, to a semiconductor package and a method of manufacturing the same by which thermal conductivity may be increased by using relatively thin metal pattern layers and heat release metal layers and heat emission effect occurring due to contact with a coolant may be increased by using a relatively thick heat sink.

### 2. Description of the Related Art

As well known, electrical and electronic components, in particular, semiconductor components generate excessive heat while driving so that heat sink may be formed or a cooling system may be applied to prevent overheat and to maintain driving performance.

Especially, semiconductor components applied to a high power application field may efficiently prevent overheat by using a cooling system that circulates a coolant.

In such cooling system, posts contacting the circulating coolant are inserted and heat transmitted from semiconductor components to the posts is cooled. Generally, posts are bonded to a substrate by using a bonding member containing Ag or Cu interposed therebetween by soldering, sintering, or brazing.

However, as the bonding member contacts a coolant of a cooling system, the bonding member is oxidized or corroded and thereby, deteriorated. Accordingly, joint strength between the bonding member and posts may be lowered.

For example, as illustrated in FIG. 1, heat generated while driving a semiconductor chip 11 may be thermally exchanged with a coolant of a cooling system through heat radiation fins 13 bonded to a lower surface of an insulating substrate 12 and thereby, may be cooled.

As described above, when the heat radiation fins 13 are bonded to the insulating substrate 12, bonding surfaces of the heat radiation fins 13 are small and thereby, shear strength is not sufficient. In this regard, the heat radiation fins 13 may be broken by pressure of a coolant while contacting a high-pressured coolant.

Accordingly, there is a demand for the development of a technology that may increase shear strength of the heat radiation fins 13, thermal conductivity, and heat emission effect.

### SUMMARY OF THE INVENTION

The present invention provides a semiconductor package and a method of manufacturing the same by which thermal conductivity may be increased by using relatively thin metal pattern layers and heat release metal layers and heat emission effect occurring due to contact with a coolant may be increased by using a relatively thick heat sink.

According to an aspect of the present invention, there is provided a semiconductor package including: at least one insulating substrate on which at least one insulating layer is formed; at least one metal pattern layer formed on one surface of the insulating layer; at least one heat release metal layer formed on the other surface of the insulating layer; at least one semiconductor chip including lower surfaces bonded to the metal pattern layer and upper surfaces bonded to at least one electrical connecting member; a molding housing covering the at least one semiconductor chip and a part of or entire metal pattern layers; at least one terminal including one end electrically or structurally connected to the insulating substrate and the other end exposed to the outside of the molding housing; and at least one heat sink including heat radiation pads and at least one heat radiation fins structurally connected thereto, at least one surface partially or entirely exposed from the lower surface, the upper surface, or the lower and upper surfaces of the molding housing, and the other surfaces structurally bonded to the heat release metal layers, wherein the thickness of the heat sink is greater than the sum of the thickness of the metal pattern layer and the thickness of the heat release metal layer and the total area of the at least one heat radiation pad is smaller than the total area of the heat release metal layers.

Here, a metal bonding layer having a thickness smaller than the thickness of the metal pattern layer may be further formed between the insulating layer and the metal pattern layer or a metal bonding layer having a thickness smaller than the thickness of the heat release metal layer may be further formed between the insulating layer and the metal pattern layer.

Also, the heat sink and the heat release metal layer may be structurally bonded to each other by using bonding members, and the bonding members may be formed of a single material including any one of Sn, Ag, Au, Cu, Ti, Ni, Pd, and ceramic or contain 30% or more of at least any one of Sn, Ag, Au, Cu, Ti, Ni, Pd, and ceramic.

Here, the thickness of the bonding member may be 1 μm through 10 mm.

Also, the heat radiation fins may partially or entirely contain at least one plating layer and the thickness of the plating layer may be 0.1 μm through 100 μm.

Here, the last plating layer from among the plating layers may be formed of a single metal such as Ni or a metal containing 50% of more of Ni.

Also, the bonding member may have a melting point of 100° C. through 250° C.

Also, one or more pores may be formed between the heat radiation pad and the heat release metal layer.

Here, the total area of the pores may be below 50% of the total area of the at least one heat radiation pad.

Also, one or more bonding gaps may be formed between the heat radiation pad and the heat release metal layer.

Here, the height of the bonding gap may be above 0.01 μm.

Also, the heat sinks and the heat release metal layers may be structurally bonded to each other by using an ultrasonic source.

Also, joint shear strength between the heat sinks and the heat release metal layers may be above 2 Kgf.

Also, the heat radiation pads or the heat radiation fins may be formed of a single material including Al or Cu or contain 30% or more of Al or Cu.

Also, the heat radiation pad may have a quadrangular shape or a square shape.

Also, the surfaces of the heat release metal layers may be plated with 80% or more of heat release metal materials and metal materials other than the heat release metal materials.

Also, the molding housing may be a compound containing an epoxy component.

Also, the semiconductor chips may be semiconductor devices containing at least any one of MOSFET, IGBT, a GaN device, a SiC device, and Ga.

Also, the at least one heat sink may directly contact cooling water in a cooling system.

Also, the electrical connecting members may be wires, clips using metal plates, or spacers formed of metal components.

Also, the heat release metal layers and the heat sinks may be mainly formed of a metal material including metal components that are same as each other by 50% or above.

Also, the insulating layer may be formed of a single material including any one of Al₂O₃, AlN, Si₃N₄, and PI or a composite material containing at least any one of Al₂O₃, AlN, Si₃N₄, and PI.

Also, the surfaces of the at least one terminal disposed outside of the molding housing may be partially or entirely plated with a material other than the material of the terminal.

Also, a bonding process of the heat sinks to the heat release metal layers may be performed after a bonding process of the at least one semiconductor chip to the metal pattern layers.

According to another aspect of the present invention, there is provided a method of manufacturing a semiconductor package including: a first step for preparing at least one insulating substrate on which at least one insulating layer is formed; a second step for forming at least one metal pattern layer formed on one surface of the insulating layer; a third step for forming at least one heat release metal layer formed on the other surface of the insulating layer; a fourth step for bonding the lower surfaces of the least one semiconductor chip to the metal pattern layer and bonding at least one electrical connecting member to the upper surfaces of the least one semiconductor chip; a fifth step for electrically or structurally connecting one end of the at least one terminal to the insulating substrate and exposing the other end of the at least one terminal to the outside of the molding housing; a sixth step for partially or entirely exposing at least one surface of at least one heat sink, to which heat radiation pads and at least one heat radiation fins are structurally connected, from the lower surface, the upper surface, or the lower and upper surfaces of the molding housing and structurally bonding the other surfaces of at least one heat sink to the heat release metal layers; and a seventh step for forming the molding housing that covers the at least one semiconductor chip and a part of or entire metal pattern layers, wherein the thickness of the heat sink is greater than the sum of the thickness of the metal pattern layer and the thickness of the heat release metal layer and the total area of the at least one heat radiation pad is smaller than the total area of the heat release metal layers.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a structure of a semiconductor package according to a prior art;

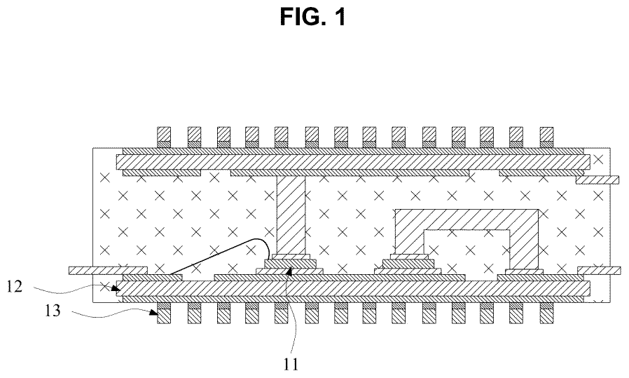

FIG. 2 is a cross-sectional view of a semiconductor package according to an embodiment of the present invention;

FIG. 3 illustrates a bonding structure of a heat sink in the semiconductor package of FIG. 2;

FIG. 4 illustrates pores in the bonding structure of FIG. 3;

FIG. 5 illustrates an ultrasonic bonding structure of a heat sink in the semiconductor package of FIG. 2;

FIG. 6 illustrates bonding gaps of a heat sink in the semiconductor package of FIG. 2;

FIG. 7 is a picture showing the bonding gaps of FIG. 6 taken by a micro electro-mechanical system (MEMS);

FIG. 8 illustrates a cooling structure of the semiconductor package of FIG. 2; and

FIG. 9 is a flowchart illustrating a method of manufacturing a semiconductor package according to another embodiment of the present invention.

### DETAILED DESCRIPTION OF THE INVENTION

Hereinafter, embodiments of the present invention will be described in more detail with reference to accompanying drawings.

A semiconductor package according to an embodiment of the present invention includes at least one insulating substrate 110 on which at least one insulating layer 111 is formed, at least one metal pattern layer 120 formed on one surface of the insulating layer 111, at least one heat release metal layer 130 formed on the other surface of the insulating layer 111, at least one semiconductor chip 140 including lower surfaces bonded to the metal pattern layer 120 and upper surfaces bonded to at least one electrical connecting member 141, a molding housing 150 covering the at least one semiconductor chip 140 and a part of or entire metal pattern layers 120, at least one terminal 160 including one end electrically or structurally connected to the insulating substrate 110 and the other end exposed to the outside of the molding housing 150, and at least one heat sink 170 including heat radiation pads 171 and at least one heat radiation fins 172 structurally connected thereto, at least one surface partially or entirely exposed from the lower surface, the upper surface, or the lower and upper surfaces of the molding housing 150, and the other surfaces structurally bonded to the heat release metal layers 130. Here, a thickness T1 of the heat sink 170 may be greater than the sum of a thickness of the metal pattern layer 120 and a thickness of the heat release metal layer 130 and the total area of the at least one heat radiation pad 171 may be smaller than the total area of the heat release metal layers 130. Accordingly, thermal conductivity may be increased by relatively thin metal pattern layers 120 and heat release metal layers 130 and heat emission effect occurring due to contact with cooling water may be increased by relatively thick heat sinks 170.

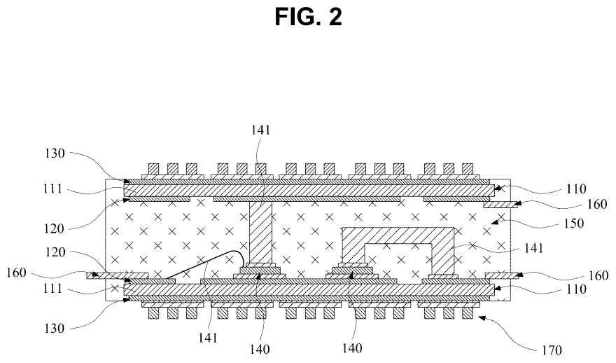

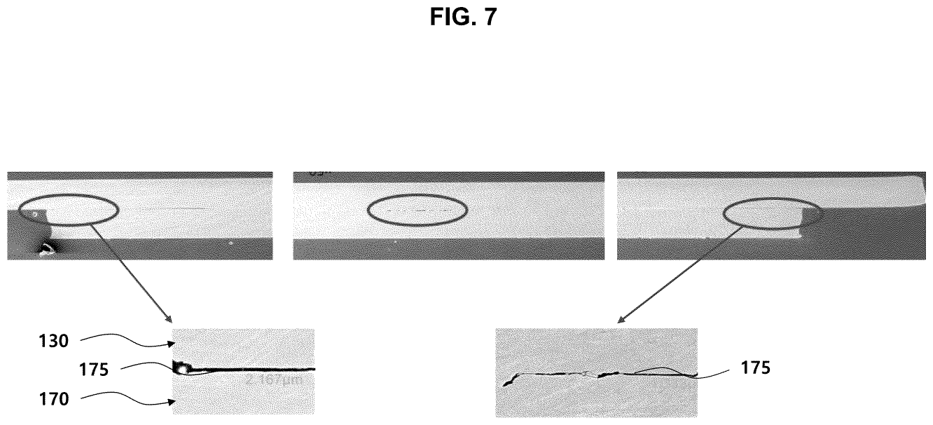

Hereinafter, the semiconductor package described above will be described in more detail below with reference to FIGS. 2 through 8.

First, referring to FIG. 2, one or more insulating substrates 110 are formed and include at least one insulating layer 111, wherein at least one metal pattern layer 120 is formed on one surface of the insulating layer 111 and at least one heat release metal layer 130 is formed on the other surface of the insulating layer 111.

Here, the insulating layer 111 may be formed of a single material including any one of Al₂O₃, AlN, Si₃N₄, and PI or a composite material containing at least any one of Al₂O₃, AlN, Si₃N₄, and PI.

For example, the insulating substrates 110 may include the at least one insulating layer 111, the at least one metal pattern layer 120, and the at least one heat release metal layer 130.

As such, the insulating substrate 110 including the insulating layers 111, the metal pattern layers 120, and the heat release metal layers 130 may be an upper substrate, a lower substrate, or both upper and lower substrates of a semiconductor package.

Next, referring to FIG. 2, one or more metal pattern layers 120 are formed on one surface of the insulating layer 111 and are electrically connected to the semiconductor chips 140.

Next, referring to FIG. 2, one or more heat release metal layers 130 are formed on the other surface of the insulating layer 111 so that heat generated while driving the semiconductor chips 140 may be emitted to the outside through the heat sinks 170.

Here, the surfaces of the heat release metal layers 130 may be plated with 80% or more of heat release metal materials and metal materials other than the heat release metal materials.

Next, referring to FIG. 2, one or more semiconductor chips 140 are formed, wherein the lower surfaces of the semiconductor chips 140 are bonded to the metal pattern layer 120 and the at least one electrical connecting member 141 is bonded to the upper surfaces of the semiconductor chips 140 so that an electrical signal may be applied.

Here, the semiconductor chips 140 may be semiconductor devices containing at least any one of MOSFET, IGBT, a GaN device, a SiC device, and Ga and, in particular, a power conversion semiconductor device.

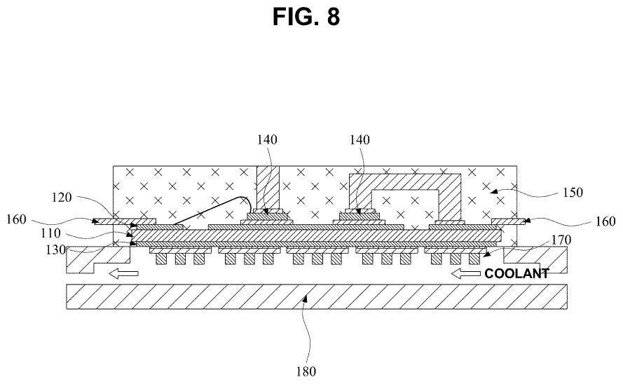

That is, such semiconductor chips 140 may be applied to devices such as inverters, converters, or on board chargers (OBC) that convert or control power. Also, while power is converted into a particular current, a particular voltage, or power having a particular frequency, excessive heat may be generated and may be cooled through a cooling system 180 (refer to FIG. 8).

In addition, the electrical connecting members 141 may be wires, clips using metal plates, or spacers formed of metal components.

Next, referring to FIG. 2, the molding housing 150 may be molded and formed to cover the at least semiconductor chip 140 and a part of or entire metal pattern layers 120 and may be a compound containing an epoxy component.

Next, referring to FIG. 2, one or more terminals 160 are formed, wherein one end of the terminal 160 is electrically or structurally connected to the insulating substrate 110 and the other end of the terminal 160 is exposed to the outside of the molding housing 150.

Also, the surfaces of the at least one terminal 160 disposed outside of the molding housing 150 are partially or entirely plated with a material other than the material of the terminal 160 and thereby, the terminals 160 exposed to the outside of the molding housing 150 may be protected.

Next, referring to FIGS. 2 through 7, one or more heat sinks 170 are formed and include the heat radiation pads 171 and the at least one heat radiation fins 172 structurally connected thereto, wherein at least one surface of the heat sinks 170 is partially or entirely exposed from the lower surface, the upper surface, or the lower and upper surfaces of the molding housing 150 and the other surfaces of the heat sinks 170 are structurally bonded to the heat release metal layers 130.

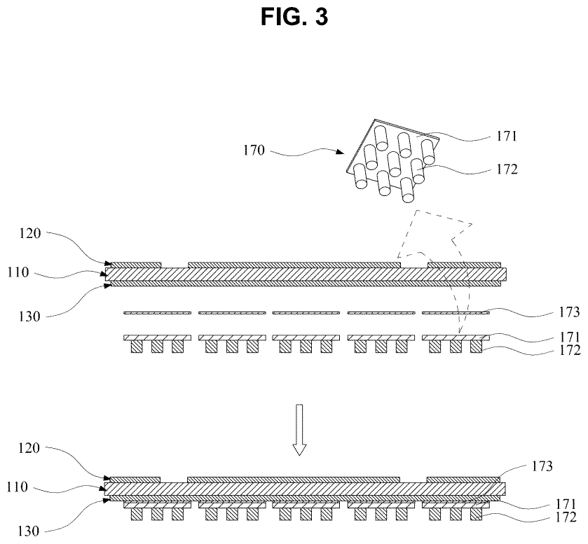

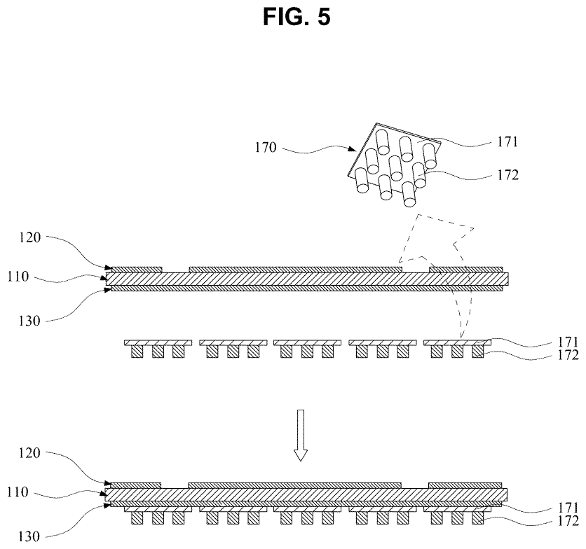

As illustrated in FIGS. 3 and 5, a plurality of heat radiation fins 172 is formed upright on the heat radiation pad 171 having a relatively large area and a plurality of heat sinks 170 formed by being divided into small pieces is respectively bonded to the heat release metal layer 130. In this regard, bonding of the heat sinks 170 is easier than bonding of a single-body heat sink and a warpage phenomenon between the heat sinks 170 and the heat release metal layers 130 occurring due to a CTE difference may be minimized.

Meanwhile, the cooling system 180 (refer to FIG. 8) may be have a double-sided heat radiation structure that applies a double-sided substrate including an upper insulating substrate and a lower insulating substrate. In this case, the heat sinks 170 on the upper insulating substrate and the heat sinks 170 on the lower insulating substrate are all bonded to each other by bonding members 173 or ultrasonic waves. Also, any one of the heat sinks 170 may be bonded using the bonding members 173 and the other one of the heat sinks 170 may be bonded using ultrasonic waves.

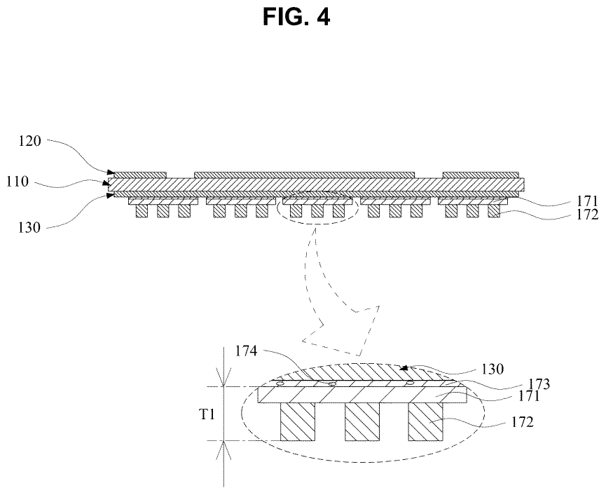

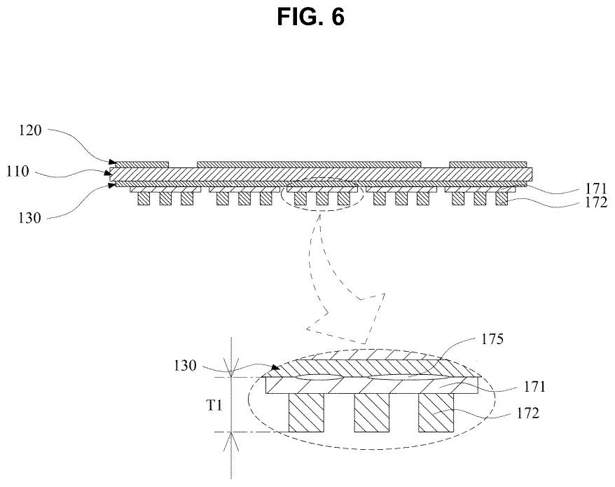

In addition, as illustrated in FIGS. 4 and 6, the thickness T1 of the heat sink 170 may be greater than the sum of the thickness of the metal pattern layer 120 and the thickness of the heat release metal layer 130 and the total area of the at least one heat radiation pad 171 may be smaller than the total area of the heat release metal layers 130. Accordingly, as the thickness of the metal pattern layer 120 and the thickness of the heat release metal layer 130 are relatively thin, heat generated while driving the semiconductor chips 140 may be emitted to the outside at the most. Also, as the thickness T1 of the heat sink 170 is relatively thick, an area that directly contacts a coolant of the cooling system 180, specifically, cooling water of a water cooling system, may be maximized and thereby, heat emission effect for heat transmitted to the heat sinks 170 may be maximized.

Here, although not illustrated, a metal bonding layer having a thickness smaller than the thickness of the metal pattern layer 120 or the thickness of the heat release metal layer 130 may be further formed between the insulating layer 111 and the metal pattern layer 120 or the insulating layer 111 and the heat release metal layer 130 and thereby, joint strength between the metal pattern layer 120 and the heat release metal layer 130 with respect to the insulating layer 111 may be increased by the metal bonding layer.

Also, as illustrated in FIGS. 3 and 4, structural bonding of the heat sinks 170 to the heat release metal layers 130 may be performed by soldering or sintering using the bonding members 173. Here, the bonding members 173 may be formed of a single material including any one of Sn, Ag, Au, Cu, Ti, Ni, Pd, and ceramic or may contain 30% or more of at least any one of Sn, Ag, Au, Cu, Ti, Ni, Pd, and ceramic.

In addition, a thickness of the bonding members 173 may be 1 μm through 10 mm so that joint strength between the heat sinks 170 and the heat release metal layers 130 may be well maintained.

Moreover, the heat radiation fins 172 may partially or entirely contain at least one plating layer (not illustrated), wherein a thickness of the plating layer may be 0.1 μm through 100 μm. Although one or more plating layers are included, the total thickness of the plating layer may be 0.1 μm through 100 μm.

Preferably, the last plating layer from among the plating layers (that is, the plating layer at the most outer part directly contacting cooling water) may be formed of a single metal such as Ni having excellent oxidation resistance or a metal containing 50% of more of Ni so that oxidation due to cooling water may be minimized.

Also, the bonding members 173 may be formed of a material having a melting point of 100° C. through 250° C. Since the heat sinks 170 are bonded after the semiconductor chips 140 and the electrical connecting members 141 are bonded, the bonding members 173 may be formed of a material having a melting point relatively lower than a melting point of binders within the package so that the binders used to bond the semiconductor chips 140 and the electrical connecting members 141 are not re-melted.

That is, a bonding process of the heat sinks 170 to the heat release metal layers 130 may be preferably performed after a bonding process of the at least one semiconductor chip 140 to the metal pattern layers 120.

Meanwhile, as illustrated in an enlarged view of FIG. 4, when the heat sink 170 is bonded to the heat release metal layer 130 by using the bonding member 173, one or more pores 174 may be formed between the heat radiation pad 171 and the heat release metal layer 130 to form a void so that stress applied to the insulating substrate 110, the metal pattern layer 120, the heat release metal layer 130, or the semiconductor chip 140 may be reduced or dispersed and thereby, structural stability may be increased.

For example, the total area of the pores 174 may be below 50% of the total area of the at least one heat radiation pad 171. In this regard, stress may be reduced and excellent joint strength of the bonding members 173 may be maintained.

Also, as illustrated in FIGS. 5 through 7, the heat sinks 170 and the heat release metal layers 130 may be structurally bonded to each other by using an ultrasonic source. In this case, one or more bonding gaps 175 may be formed between the heat radiation pad 171 and the heat release metal layer 130 and may preferably have a thickness of above 0.01 μm.

As such, the bonding gaps 175 may be used to reduce or disperse stress applied to the insulating substrate 110, the metal pattern layer 120, the heat release metal layer 130, or the semiconductor chip 140 and thereby, structural stability may be increased.

Meanwhile, joint shear strength between the heat sinks 170 and the heat release metal layers 130 may be preferably above 2 Kgf. In this regard, the maximum load required to be broken due to shear (sliding) between the heat sinks 170 and the heat release metal layers 130 may be increased and thereby, structural integrity of a joint area may be improved.

Also, the heat radiation pads 171 or the heat radiation fins 172 may be formed of a single material including Al or Cu or may contain 30% or more of Al or Cu so that excellent thermal conductivity may be provided so as to increase heat emission effect.

In addition, as illustrated in FIGS. 3 and 5, the heat radiation pad 171 may have a quadrangular shape or a square shape and thereby, may be closely bonded to the plurality of heat sinks 170 formed by being divided into small pieces. Accordingly, bonding therebetween may be performed while gaps are minimized and thus, the heat sinks 170 may have a structure that is same as that of a single-body heat sink.

Meanwhile, referring to FIG. 8, one or more heat sinks 170 directly contact a coolant, for example, cooling water, within the cooling system 180, to exchange heat and thereby, may emit heat.

Also, the heat release metal layers 130 and the heat sinks 170 may be mainly formed of a metal material including metal components that are same as each other by 50% or above. In this regard, thermal conductivity that is similar to or same as that of in a conventional art may be maintained and thereby, excellent heat emission effect may be provided.

In addition, a coolant that circulates an inlet and an outlet of the cooling system 180 may be a coolant fluid, cooling gas, and/or air (cold air). That is, a coolant may be selected from any one of cooling water, a cooling liquid containing cooling water, air (cold air), and nitrogen or may include at least any one of cooling water, a cooling liquid containing cooling water, air (cold air), and nitrogen.

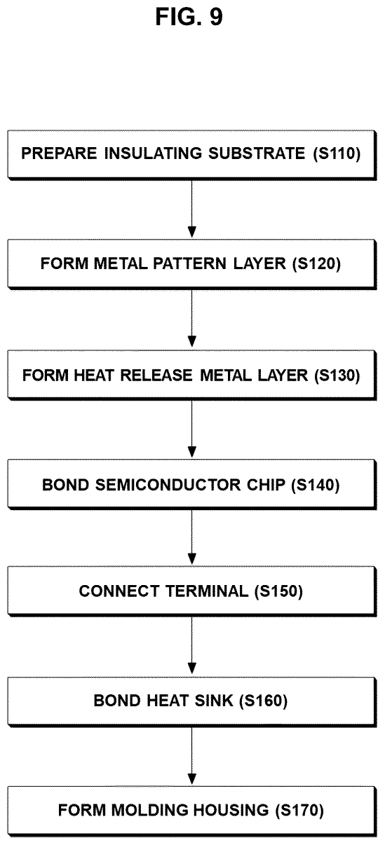

Meanwhile, referring to FIG. 9, a method of manufacturing a semiconductor package according to another embodiment of the present invention includes a first step S110 for preparing the at least one insulating substrate 110 on which the at least one insulating layer 111 is formed, a second step S120 for forming the at least one metal pattern layer 120 formed on one surface of the insulating layer 111, a third step S130 for forming the at least one heat release metal layer 130 formed on the other surface of the insulating layer 111, a fourth step S140 for bonding the lower surfaces of the least one semiconductor chip 140 to the metal pattern layer 120 and bonding the at least one electrical connecting member 141 to the upper surfaces of the least one semiconductor chip 140, a fifth step S150 for electrically or structurally connecting one end of the at least one terminal 160 to the insulating substrate 110 and exposing the other end of the at least one terminal 160 to the outside of the molding housing 150, a sixth step S160 for partially or entirely exposing at least one surface of the at least one heat sink 170, to which the heat radiation pads 171 and the at least one heat radiation fins 172 are structurally connected, from the lower surface, the upper surface, or the lower and upper surfaces of the molding housing 150 and structurally bonding the other surfaces of the at least one heat sink 170 to the heat release metal layers 130, and a seventh step S170 for forming the molding housing 150 that covers the at least one semiconductor chip 140 and a part of or entire metal pattern layers 120.

Here, the thickness T1 of the heat sink 170 may be greater than the sum of the thickness of the metal pattern layer 120 and the thickness of the heat release metal layer 130 and the total area of the at least one heat radiation pad 171 may be smaller than the total area of the heat release metal layers 130. Accordingly, thermal conductivity may be increased by relatively thin metal pattern layers 120 and heat release metal layers 130 and heat emission effect occurring due to contact with cooling water may be increased by relatively thick heat sinks 170.

More specifically, referring firstly to FIG. 2, one or more insulating substrates 110 are formed and include the at least one insulating layer 111, wherein the at least one metal pattern layer 120 is formed on one surface of the insulating layer 111 and the at least one heat release metal layer 130 is formed on the other surface of the insulating layer 111.

Here, the insulating layer 111 may be formed of a single material including any one of Al₂O₃, AlN, Si₃N₄, and PI or a composite material containing at least any one of Al₂O₃, AlN, Si₃N₄, and PI.

For example, the insulating substrates 110 may include the at least one insulating layer 111, the at least one metal pattern layer 120, and the at least one heat release metal layer 130.

As such, the insulating substrate 110 including the insulating layers 111, the metal pattern layers 120, and the heat release metal layers 130 may be an upper substrate, a lower substrate, or both upper and lower substrates of a semiconductor package.

Next, referring to FIG. 2, one or more metal pattern layers 120 are formed on one surface of the insulating layer 111 and are electrically connected to the semiconductor chips 140.

Next, referring to FIG. 2, one or more heat release metal layers 130 are formed on the other surface of the insulating layer 111 so that heat generated while driving the semiconductor chips 140 may be emitted to the outside through the heat sinks 170.

Here, the surfaces of the heat release metal layers 130 may be plated with 80% or more of heat release metal materials and metal materials other than the heat release metal materials.

Next, referring to FIG. 2, one or more semiconductor chips 140 are formed, wherein the lower surfaces of the semiconductor chips 140 are bonded to the metal pattern layer 120 and the at least one electrical connecting member 141 is bonded to the upper surfaces of the semiconductor chips 140 so that an electrical signal may be applied.

Here, the semiconductor chips 140 may be semiconductor devices containing at least any one of MOSFET, IGBT, a GaN device, a SiC device, and Ga and, in particular, a power conversion semiconductor device.

That is, such semiconductor chips 140 may be applied to devices such as inverters, converters, or on board chargers (OBC) that convert or control power. Also, while power is converted into a particular current, a particular voltage, or power having a particular frequency, excessive heat may be generated and may be cooled through the cooling system 180 (refer to FIG. 8).

In addition, the electrical connecting members 141 may be wires, clips using metal plates, or spacers formed of metal components.

Next, referring to FIG. 2, the molding housing 150 may be molded and formed to cover the at least semiconductor chip 140 and a part of or entire metal pattern layers 120 and may be a compound containing an epoxy component.

Next, referring to FIG. 2, one or more terminals 160 are formed, wherein one end of the terminal 160 is electrically or structurally connected to the insulating substrate 110 and the other end of the terminal 160 is exposed to the outside of the molding housing 150.

Also, the surfaces of the at least one terminal 160 disposed outside of the molding housing 150 are partially or entirely plated with a material other than the material of the terminal 160 and thereby, the terminals 160 exposed to the outside of the molding housing 150 may be protected.

Next, referring to FIGS. 2 through 7, one or more heat sinks 170 are formed and include the heat radiation pads 171 and the at least one heat radiation fins 172 structurally connected thereto, wherein at least one surface of the heat sinks 170 is partially or entirely exposed from the lower surface, the upper surface, or the lower and upper surfaces of the molding housing 150 and the other surfaces of the heat sinks 170 are structurally bonded to the heat release metal layers 130.

As illustrated in FIGS. 3 and 5, the plurality of heat radiation fins 172 is formed upright on the heat radiation pad 171 having a relatively large area and the plurality of heat sinks 170 formed by being divided into small pieces is respectively bonded to the heat release metal layer 130. In this regard, bonding of the heat sinks 170 is easier than bonding of a single-body heat sink and a warpage phenomenon between the heat sinks 170 and the heat release metal layers 130 occurring due to a CTE difference may be minimized.

In addition, as illustrated in FIGS. 4 and 6, the thickness T1 of the heat sink 170 may be greater than the sum of the thickness of the metal pattern layer 120 and the thickness of the heat release metal layer 130 and the total area of the at least one heat radiation pad 171 may be smaller than the total area of the heat release metal layers 130. Accordingly, as the thickness of the metal pattern layer 120 and the thickness of the heat release metal layer 130 are relatively thin, heat generated while driving the semiconductor chips 140 may be emitted to the outside at the most. Also, as the thickness T1 of the heat sink 170 is relatively thick, an area that directly contacts a coolant of the cooling system 180, specifically, cooling water of a water cooling system, may be maximized and thereby, heat emission effect for heat transmitted to the heat sinks 170 may be maximized.

Here, although not illustrated, a metal bonding layer having a thickness smaller than the thickness of the metal pattern layer 120 or the thickness of the heat release metal layer 130 may be further formed between the insulating layer 111 and the metal pattern layer 120 or the insulating layer 111 and the heat release metal layer 130 and thereby, joint strength between the metal pattern layer 120 and the heat release metal layer 130 with respect to the insulating layer 111 may be increased by the metal bonding layer.

Also, as illustrated in FIGS. 3 and 4, structural bonding of the heat sinks 170 to the heat release metal layers 130 may be performed by soldering or sintering using the bonding members 173. Here, the bonding members 173 may be formed of a single material including any one of Sn, Ag, Au, Cu, Ti, Ni, Pd, and ceramic or may contain 30% or more of at least any one of Sn, Ag, Au, Cu, Ti, Ni, Pd, and ceramic.

In addition, the thickness of the bonding members 173 may be 1 μm through 10 mm so that joint strength between the heat sinks 170 and the heat release metal layers 130 may be well maintained.

Moreover, the heat radiation fins 172 may partially or entirely contain at least one plating layer (not illustrated), wherein the thickness of the plating layer may be 0.1 μm through 100 μm. Although one or more plating layers are included, the total thickness of the plating layer may be 0.1 μm through 100 μm.

Preferably, the last plating layer from among the plating layers (that is, the plating layer at the most outer part directly contacting cooling water) may be formed of a single metal such as Ni having excellent oxidation resistance or a metal containing 50% of more of Ni so that oxidation due to cooling water may be minimized.

Also, the bonding members 173 may be formed of a material having a melting point of 100° C. through 250° C. Since the heat sinks 170 are bonded after the semiconductor chips 140 and the electrical connecting members 141 are bonded, the bonding members 173 may be formed of a material having a melting point relatively lower than a melting point of binders within the package so that the binders used to bond the semiconductor chips 140 and the electrical connecting members 141 are not re-melted.

That is, a bonding process of the heat sinks 170 to the heat release metal layers 130 may be preferably performed after a bonding process of the at least one semiconductor chip 140 to the metal pattern layers 120.

Meanwhile, as illustrated in an enlarged view of FIG. 4, when the heat sink 170 is bonded to the heat release metal layer 130 by using the bonding member 173, one or more pores 174 may be formed between the heat radiation pad 171 and the heat release metal layer 130 to form a void so that stress applied to the insulating substrate 110, the metal pattern layer 120, the heat release metal layer 130, or the semiconductor chip 140 may be reduced or dispersed and thereby, structural stability may be increased.

For example, the total area of the pores 174 may be below 50% of the total area of the at least one heat radiation pad 171. In this regard, stress may be reduced and excellent joint strength of the bonding members 173 may be maintained.

Also, as illustrated in FIGS. 5 through 7, the heat sinks 170 and the heat release metal layers 130 may be structurally bonded to each other by using an ultrasonic source. In this case, one or more bonding gaps 175 may be formed between the heat radiation pad 171 and the heat release metal layer 130 and may preferably have a thickness of above 0.01 μm.

As such, the bonding gaps 175 may be used to reduce or disperse stress applied to the insulating substrate 110, the metal pattern layer 120, the heat release metal layer 130, or the semiconductor chip 140 and thereby, structural stability may be increased.

Meanwhile, joint shear strength between the heat sinks 170 and the heat release metal layers 130 may be preferably above 2 Kgf. In this regard, the maximum load required to be broken due to shear (sliding) between the heat sinks 170 and the heat release metal layers 130 may be increased and thereby, structural integrity of a joint area may be improved.

Also, the heat radiation pads 171 or the heat radiation fins 172 may be formed of a single material including Al or Cu or may contain 30% or more of Al or Cu so that excellent thermal conductivity may be provided so as to increase heat emission effect.

In addition, as illustrated in FIGS. 3 and 5, the heat radiation pad 171 may have a quadrangular shape or a square shape and thereby, may be closely bonded to the plurality of heat sinks 170 formed by being divided into small pieces. Accordingly, bonding therebetween may be performed while gaps are minimized and thus, the heat sinks 170 may have a structure that is same as that of a single-body heat sink.

Meanwhile, referring to FIG. 8, one or more heat sinks 170 directly contact a coolant, for example, cooling water, within the cooling system 180, to exchange heat and thereby, may emit heat.

Also, the heat release metal layers 130 and the heat sinks 170 may be mainly formed of a metal material including metal components that are same as each other by 50% or above.. In this regard, thermal conductivity that is similar to or same as that of in a conventional art may be maintained and thereby, excellent heat emission effect may be provided.

In the semiconductor package and the method of manufacturing the same described above, thermal conductivity may be increased by relatively thin metal pattern layers and heat release metal layers and heat emission effect occurring due to contact with cooling water may be increased by relatively thick heat sinks. Also, a plurality of heat radiation fins is formed upright on the heat radiation pad having a relatively large area and a plurality of heat sinks formed by being divided into small pieces is respectively bonded to the heat release metal layer. In this regard, bonding of the heat sinks is easier than bonding of a single-body heat sink and a warpage phenomenon between the heat sinks and the heat release metal layers occurring due to a CTE difference may be minimized.

According to the present invention, thermal conductivity may be increased by relatively thin metal pattern layers and heat release metal layers and heat emission effect occurring due to contact with cooling water may be increased by relatively thick heat sinks. Also, a plurality of heat radiation fins is formed upright on the heat radiation pad having a relatively large area and a plurality of heat sinks formed by being divided into small pieces is respectively bonded to the heat release metal layer. In this regard, bonding of the heat sinks is easier than bonding of a single-body heat sink and a warpage phenomenon between the heat sinks and the heat release metal layers occurring due to a CTE difference may be minimized.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
at least one insulating substrate on which at least one insulating layer is formed;
at least one metal pattern layer formed on one surface of the insulating layer;
at least one heat release metal layer formed on the other surface of the insulating layer;
at least one semiconductor chip comprising lower surfaces bonded to the metal pattern layer and upper surfaces bonded to at least one electrical connecting member;
a molding housing covering the at least one semiconductor chip and a part of or entire metal pattern layers;
at least one terminal comprising one end electrically or structurally connected to the insulating substrate and the other end exposed to the outside of the molding housing; and
at least one heat sink comprising heat radiation pads and at least one heat radiation fins structurally connected thereto, at least one surface partially or entirely exposed from the lower surface, the upper surface, or the lower and upper surfaces of the molding housing, and the other surfaces structurally bonded to the heat release metal layers, wherein the thickness of the heat sink is greater than the sum of the thickness of the metal pattern layer and the thickness of the heat release metal layer and the total area of the at least one heat radiation pad is smaller than the total area of the heat release metal layers.

2. The semiconductor package of claim 1, further comprising a metal bonding layer having a thickness smaller than the thickness of the metal pattern layer between the insulating layer and the metal pattern layer or a metal bonding layer having a thickness smaller than the thickness of the heat release metal layer between the insulating layer and the metal pattern layer.

3. The semiconductor package of claim 1, wherein the heat sink and the heat release metal layer are structurally bonded to each other by using bonding members, and the bonding members are formed of a single material comprising any one of Sn, Ag, Au, Cu, Ti, Ni, Pd, and ceramic or contain 30% or more of at least any one of Sn, Ag, Au, Cu, Ti, Ni, Pd, and ceramic.

4. The semiconductor package of claim 3, wherein the thickness of the bonding member is 1 μm through 10 mm.

5. The semiconductor package of claim 1, wherein the heat radiation fins partially or entirely contain at least one plating layer and the thickness of the plating layer is 0.1 μm through 100 μm.

6. The semiconductor package of claim 5, wherein the last plating layer from among the plating layers is formed of a single metal such as Ni or a metal containing 50% of more of Ni.

7. The semiconductor package of claim 3, wherein the bonding member has a melting point of 100° C. through 250° C.

8. The semiconductor package of claim 1, wherein one or more pores are formed between the heat radiation pad and the heat release metal layer.

9. The semiconductor package of claim 8, wherein the total area of the pores is below 50% of the total area of the at least one heat radiation pad.

10. The semiconductor package of claim 1, wherein one or more bonding gaps are formed between the heat radiation pad and the heat release metal layer.

11. The semiconductor package of claim 10, wherein the height of the bonding gap is above 0.01 μm.

12. The semiconductor package of claim 1, wherein the heat sinks and the heat release metal layers are structurally bonded to each other by using an ultrasonic source.

13. The semiconductor package of claim 1, wherein joint shear strength between the heat sinks and the heat release metal layers is above 2 Kgf.

14. The semiconductor package of claim 1, wherein the heat radiation pad has a quadrangular shape or a square shape.

15. The semiconductor package of claim 1, wherein the surfaces of the heat release metal layers are plated with 80% or more of heat release metal materials and metal materials other than the heat release metal materials.

16. The semiconductor package of claim 1, wherein the molding housing is a compound containing an epoxy component.

17. The semiconductor package of claim 1, wherein the at least one heat sink directly contact cooling water in a cooling system.

18. The semiconductor package of claim 1, wherein the electrical connecting members are wires, clips using metal plates, or spacers formed of metal components.

19. The semiconductor package of claim 1, wherein the heat release metal layers and the heat sinks are mainly formed of a metal material comprising metal components that are same as each other by 50% or above.

20. The semiconductor package of claim 1, wherein the surfaces of the at least one terminal disposed outside of the molding housing are partially or entirely plated with a material other than the material of the terminal.

21. The semiconductor package of claim 1, wherein a bonding process of the heat sinks to the heat release metal layers is performed after a bonding process of the at least one semiconductor chip to the metal pattern layers.

22. A method of manufacturing a semiconductor package, the method comprising:
a first step for preparing at least one insulating substrate on which at least one insulating layer is formed;
a second step for forming at least one metal pattern layer formed on one surface of the insulating layer;
a third step for forming at least one heat release metal layer formed on the other surface of the insulating layer;
a fourth step for bonding the lower surfaces of the least one semiconductor chip to the metal pattern layer and bonding at least one electrical connecting member to the upper surfaces of the least one semiconductor chip;
a fifth step for electrically or structurally connecting one end of the at least one terminal to the insulating substrate and exposing the other end of the at least one terminal to the outside of the molding housing;
a sixth step for partially or entirely exposing at least one surface of at least one heat sink, to which heat radiation pads and at least one heat radiation fins are structurally connected, from the lower surface, the upper surface, or the lower and upper surfaces of the molding housing and structurally bonding the other surfaces of at least one heat sink to the heat release metal layers; and
a seventh step for forming the molding housing that covers the at least one semiconductor chip and a part of or entire metal pattern layers, wherein the thickness of the heat sink is greater than the sum of the thickness of the metal pattern layer and the thickness of the heat release metal layer and the total area of the at least one heat radiation pad is smaller than the total area of the heat release metal layers.
